(19) United States
(12) Patent Application Publication
(10) Pub. No.: US 2023/0422639 A1
(43) Pub. Date: Dec. 28, 2023

(54) SEMICONDUCTOR STRUCTURE INCLUDING BARRIER LAYER BETWEEN ELECTRODE LAYER AND UNDERLYING SUBSTRATE

(71) Applicant: Intel Corporation, Santa Clara, CA (US)

(72) Inventors: Shafaat Ahmed, Albuquerque, NM (US); Gowtham Sriram Jawaharram, Rio Ranch, NM (US); Cyrus M. Fox, Rio Rancho, NM (US); Jose L. Cruz-Campa, Albuquerque, NM (US); Kriti Agarwal, Albuquerque, NM (US); Jian Jiao, Hillsboro, OR (US); Hong Li, Albuquerque, NM (US); Bharat V. Krishnan, Albuquerque, NM (US); Ervin T. Hill, III, Edgewood, NM (US)

(73) Assignee: Intel Corporation, Santa Clara, CA (US)

(21) Appl. No.: 17/850,746

(22) Filed: Jun. 27, 2022

(51) Int. Cl. H01L 45/00; H01L 23/528

(52) U.S. Cl. CPC H01L 45/06; H01L 23/5283; H01L 45/1233; H01L 45/1253

(57) ABSTRACT

A semiconductor structure, system and method. The semiconductor structure comprises: a substrate including circuitry therein; and a semiconductor stack on the substrate, the semiconductor stack including: a first electrically conductive layer including a metal and electrically coupled to the circuitry of the substrate; and a second electrically conductive layer between the substrate and the first electrically conductive layer, the second electrically conductive layer including one of a refractory metal, or a combination including silicon, carbon and nitride. The second electrically conductive layer may serve as a barrier layer between the first electrically conductive layer and the material of the underlying substrate, in this manner avoiding the formation of an intermixing region between the metal of the first electrically conductive layer and the material of the substrate during deposition of the metal.

### FIELD

The present disclosure relates in general to microelectronic memory architectures.

### BACKGROUND

Existing memory architectures in three dimensional memory devices tend to include word lines (WLs) including tungsten (W) deposited onto a tetraethoxysilane (TEOS) dielectric material, such as a TEOS silicon dioxide dielectric material. Some of the W in the WL can nucleate and grow along the <110> plane on the underlying layer, in this way advantageously leading to low resistivity of the W film on the TEOS dielectric material. WL materials have been provided using physical vapor deposition (PVD) on the substrate surface. Typically, a high strike bias in the form of an alternating current is applied to the W containing plasma to accelerate the same toward the target substrate. Doing so advantageously helps the sputtered W nucleate on the substrate along with <110> plane, achieving the low resistivity mentioned above.

### BRIEF DESCRIPTION OF THE DRAWINGS

FIG. 1 is a schematic illustration of a block diagram of components of a computer system according to some embodiments.

FIG. 2 is a schematic illustration of a memory partition in accordance with certain embodiments.

FIG. 3 is a schematic illustration of a memory array in accordance with certain embodiments.

FIG. 4A is a graph depicting memory cell threshold voltage distributions and demarcation voltages in accordance with certain embodiments for a single level cell (SLC) memory including selector devices in individual memory cells thereof.

FIG. 4B is a graph depicting memory cell threshold voltage distributions and demarcation voltages in accordance with certain embodiments for a multi-level cell (MLC) memory including selector devices in individual memory cells thereof.

FIG. 5 is a schematic perspective three-dimensional view of a semiconductor structure for a 3D memory architecture according to some embodiments.

FIG. 6A is a cross section of a transmission electron microscope (TEM) image of a semiconductor structure according to the state of the art.

FIG. 6B is a schematic cross section of a portion of the semiconductor structure of FIG. 6A.

FIG. 7A is a cross section of a TEM of a semiconductor structure according to an example embodiment.

FIG. 7B is a schematic cross section of a portion of the semiconductor structure of FIG. 7A.

FIG. 8 illustrates an example process in accordance with certain embodiments.

Like reference numbers and designations in the various drawings indicate like elements.

### DETAILED DESCRIPTION

Some embodiments provide a semiconductor structure comprising: a substrate including circuitry therein; a semiconductor stack on the substrate, the semiconductor stack including: a first electrically conductive layer including a metal and electrically coupled to the circuitry of the substrate; and a second electrically conductive layer between the substrate and the first electrically conductive layer, the second electrically conductive layer including one of a refractory metal, or a combination including silicon, carbon and nitride. The second electrically conductive layer may serve as a barrier layer between the first electrically conductive layer and the material of the underlying substrate, in this manner avoiding the formation of an intermixing region between the metal of the first electrically conductive layer and the material of the substrate during deposition of the metal.

Thus, advantageously, some embodiments provide a semiconductor structure that avoids electrical leakage resulting from an implantation or intermixing of the metal of the first electrically conductive layer into the material of the substrate, in this manner substantially lowering or preventing current leakage between components of the semiconductor structure that would have resulted from the implantation and intermixing noted above. In this manner, some embodiments allow the provision of semiconductor devices, such as those including arrays of memory cells defining pillars, that do not lead to electrical leakage as between address lines, such as WLs, of adjacent pillars, or between the WLs and the circuitry of the underlying substrate.

Although the drawings depict particular computer systems, the concepts of various embodiments are applicable to any suitable computer systems. Examples of systems in which teachings of the present disclosure may be used include desktop computer systems, server computer systems, storage systems, handheld devices, tablets, other thin notebooks, system on a chip (SOC) devices, and embedded applications. Some examples of handheld devices include cellular phones, digital cameras, media players, personal digital assistants (PDAs), and handheld PCs. Embedded applications may include microcontrollers, digital signal processors (DSPs), SOCs, network computers (NetPCs), set-top boxes, network hubs, wide area networks (WANs) switches, or any other system that can perform the functions and operations taught below. Various embodiments of the present disclosure may be used in any suitable computing environment, such as a personal computing device, a server, a mainframe, a cloud computing service provider infrastructure, a datacenter, a communications service provider infrastructure (e.g., one or more portions of an Evolved Packet Core), or other environment comprising one or more computing devices.

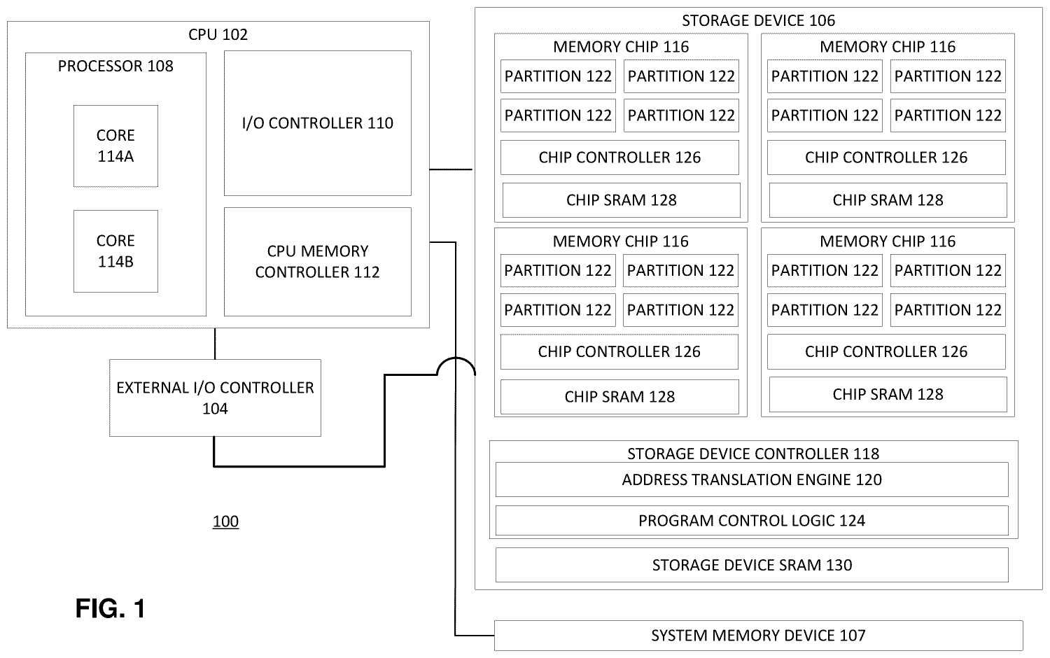

FIG. 1 illustrates a block diagram of components of a computer system 100 in accordance with some embodiments. System 100 includes a central processing unit (CPU) 102 coupled to an external input/output (I/O) controller 104, a storage device 106 such as a solid state drive (SSD), and system memory device 107. During operation, data may be transferred between a storage device 106 and/or system memory device 107 and the CPU 102. In various embodiments, particular memory access operations (e.g., read and write operations) involving a storage device 106 or system memory device 107 may be issued by an operating system and/or other software applications executed by processor 108. In various embodiments, a storage device 106 may include a storage device controller 118 and one or more memory chips 116 that each comprise any suitable number of memory partitions 122.

In various embodiments, a memory partition may include a 3D crosspoint memory array. In some embodiments, a 3D crosspoint memory array may comprise a transistor-less (i.e., at least with respect to the data storage elements of the memory) stackable crosspoint architecture in which memory cells sit at the intersection of row address lines and column address lines arranged in a grid.

During a read operation, a differential bias sometimes referred to as a demarcation voltage (VDM) may be applied across the terminals of the memory cell and the state of the memory cell may be sensed based on the reaction of the memory cell to the applied bias. For example, the memory cell may either go into a conductive ON state (logic one) or remain in a weakly conductive OFF state (logic zero). The applied voltage at which a memory cell transitions from being sensed as a logic one to being sensed as a logic zero may be termed a threshold voltage of the memory cell. Thus, as an example, when the VDM is higher than the threshold voltage of the memory cell, the memory cell may be sensed as storing a logic one and when the VDM is lower than the threshold voltage of the memory cell, the memory cell may be sensed as storing a logic zero.

CPU 102 comprises a processor 108, such as a microprocessor, an embedded processor, a DSP, a network processor, a handheld processor, an application processor, a co-processor, an SOC, or other device to execute code (i.e., software instructions). Processor 108, in the depicted embodiment, includes two processing elements (cores 114A and 114B in the depicted embodiment), which may include asymmetric processing elements or symmetric processing elements. However, a processor may include any number of processing elements that may be symmetric or asymmetric. CPU 102 may be referred to herein as a host computing device (though a host computing device may be any suitable computing device operable to issue memory access commands to a storage device 106).

In one embodiment, a processing element refers to hardware or logic to support a software thread. Examples of hardware processing elements include: a thread unit, a thread slot, a thread, a process unit, a context, a context unit, a logical processor, a hardware thread, a core, and/or any other element, which is capable of holding a state for a processor, such as an execution state or architectural state. In other words, a processing element, in one embodiment, refers to any hardware capable of being independently associated with code, such as a software thread, operating system, application, or other code. A physical processor (or processor socket) typically refers to an integrated circuit, which potentially includes any number of other processing elements, such as cores or hardware threads.

A core 114 (e.g., 114A or 114B) may refer to logic located on an integrated circuit capable of maintaining an independent architectural state, wherein each independently maintained architectural state is associated with at least some dedicated execution resources. A hardware thread may refer to any logic located on an integrated circuit capable of maintaining an independent architectural state, wherein the independently maintained architectural states share access to execution resources. As can be seen, when certain resources are shared and others are dedicated to an architectural state, the line between the nomenclature of a hardware thread and core overlaps. Yet often, a core and a hardware thread are viewed by an operating system as individual logical processors, where the operating system is able to individually schedule operations on each logical processor.

In various embodiments, the processing elements may also include one or more arithmetic logic units (ALUs), floating point units (FPUs), caches, instruction pipelines, interrupt handling hardware, registers, or other hardware to facilitate the operations of the processing elements.

I/O controller 110 is an integrated I/O controller that includes logic for communicating data between CPU 102 and I/O devices, which may refer to any suitable logic capable of transferring data to and/or receiving data from an electronic system, such as CPU 102. For example, an I/O device may comprise an audio/video (A/V) device controller such as a graphics accelerator or audio controller; a data storage device controller, such as a flash memory device, magnetic storage disk, or optical storage disk controller; a wireless transceiver; a network processor; a network interface controller; or a controller for another input device such as a monitor, printer, mouse, keyboard, or scanner; or other suitable device. In a particular embodiment, an I/O device may comprise storage device controller 118 of storage device 106 coupled to the CPU 102 through I/O controller 110.

An I/O device may communicate with the I/O controller 110 of the CPU 102 using any suitable signaling protocol, such as peripheral component interconnect (PCI), PCI Express (PCIe), Universal Serial Bus (USB), CXL, compute express link (CXL), Serial Attached SCSI (SAS), Serial ATA (SATA), Fibre Channel (FC), IEEE 802.3, IEEE 802.11, or other current or future signaling protocol. In particular embodiments, I/O controller 110 and the underlying I/O device may communicate data and commands in accordance with a logical device interface specification such as Non-Volatile Memory Express (NVMe) (e.g., as described by one or more of the specifications available at www.nvmexpress.org/specifications/) or Advanced Host Controller Interface (AHCI) (e.g., as described by one or more AHCI specifications such as Serial ATA AHCI: Specification, Rev. 1.3.1 available at http://www.intel.com/content/www/us/en/io/serial-ata/serial-ata-ahci-spec-rev1-3-1.html). In various embodiments, I/O devices coupled to the I/O controller may be located off-chip (i.e., not on the same chip as CPU 102) or may be integrated on the same chip as the CPU 102.

CPU memory controller 112 is an integrated memory controller that includes logic to control the flow of data going to and from one or more system memory devices 107. CPU memory controller 112 may include logic operable to read from a system memory device 107, write to a system memory device 107, or to request other operations from a system memory device 107. In various embodiments, CPU memory controller 112 may receive write requests from cores 114 and/or I/O controller 110 and may provide data specified in these requests to a system memory device 107 for storage therein. CPU memory controller 112 may also read data from a system memory device 107 and provide the read data to I/O controller 110 or a core 114. During operation, CPU memory controller 112 may issue commands including one or more addresses of the system memory device 107 in order to read data from or write data to memory (or to perform other operations). In some embodiments, CPU memory controller 112 may be implemented on the same chip as CPU 102, whereas in other embodiments, CPU memory controller 112 may be implemented on a different chip than that of CPU 102. I/O controller 110 may perform similar operations with respect to one or more storage devices 106.

The CPU 102 may also be coupled to one or more other I/O devices through external I/O controller 104. In a particular embodiment, external I/O controller 104 may couple a storage device 106 to the CPU 102. External I/O controller 104 may include logic to manage the flow of data between one or more CPUs 102 and I/O devices. In particular embodiments, external I/O controller 104 is located on a motherboard along with the CPU 102. The external I/O controller 104 may exchange information with components of CPU 102 using point-to-point or other interfaces.

A system memory device 107 may store any suitable data, such as data used by processor 108 to provide the functionality of computer system 100. For example, data associated with programs that are executed or files accessed by cores 114 may be stored in system memory device 107. Thus, a system memory device 107 may include a system memory that stores data and/or sequences of instructions that are executed or otherwise used by the cores 114. In various embodiments, a system memory device 107 may store persistent data (e.g., a user's files or instruction sequences) that maintains its state even after power to the system memory device 107 is removed. A system memory device 107 may be dedicated to a particular CPU 102 or shared with other devices (e.g., one or more other processors or other devices) of computer system 100.

In various embodiments, a system memory device 107 may include a memory comprising any number of memory partitions, a memory device controller, and other supporting logic (not shown). A memory module may include non-volatile memory and/or volatile memory.

Non-volatile memory is a storage medium that does not require power to maintain the state of data stored by the medium. In various embodiments, non-volatile memory may be byte or block addressable. Nonlimiting examples of nonvolatile memory may include any or a combination of: solid state memory (such as planar or 3-dimensional (3D) NAND flash memory or NOR flash memory), 3D crosspoint memory, phase change memory or SXP memory (e.g., memory that uses a chalcogenide glass phase change material in the memory cells), ferroelectric memory, silicon-oxide-nitride-oxide-silicon (SONOS) memory, polymer memory (e.g., ferroelectric polymer memory), ferroelectric transistor random access memory (Fe-TRAM) ovonic memory, anti-ferroelectric memory, nanowire memory, electrically erasable programmable read-only memory (EEPROM), a memristor, single or multi-level phase change memory (PCM), Spin Hall Effect Magnetic RAM (SHE-MRAM), and Spin Transfer Torque Magnetic RAM (STTRAM), a resistive memory, magnetoresistive random access memory (MRAM) memory that incorporates memristor technology, resistive memory including the metal oxide base, the oxygen vacancy base and the conductive bridge Random Access Memory (CB-RAM), a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory.

Volatile memory is a storage medium that requires power to maintain the state of data stored by the medium. Nonlimiting examples of volatile memory may include several types of random access memory (RAM), such as dynamic random access memory (DRAM) or static random access memory (SRAM). One particular type of DRAM that may be used in a memory module is synchronous dynamic random access memory (SDRAM). In some embodiments, any portion of memory 107 that is volatile memory can comply with JEDEC standards including but not limited to Double Data Rate (DDR) standards, e.g., DDR3, 4, and 5, or Low Power DDR4 (LPDDR4) as well as emerging standards.

A storage device 106 may store any suitable data, such as data used by processor 108 to provide functionality of computer system 100. For example, data associated with programs that are executed or files accessed by cores 114A and 114B may be stored in storage device 106. In various embodiments, a storage device 106 may store persistent data (e.g., a user's files or software application code) that maintains its state even after power to the storage device 106 is removed. A storage device 106 may be dedicated to CPU 102 or shared with other devices (e.g., another CPU or other device) of computer system 100.

In the embodiment depicted, storage device 106 includes a storage device controller 118 and four memory chips 116 each comprising four memory partitions 122 operable to store data, however, a storage device may include any suitable number of memory chips each having any suitable number of memory partitions. A memory partition 122 includes a plurality of memory cells operable to store data. The cells of a memory partition 122 may be arranged in any suitable fashion, such as in rows (e.g., wordlines) and columns (e.g., bitlines), three dimensional structures, sectors, or in other ways. In various embodiments, the cells may be logically grouped into banks, blocks, subblocks, wordlines, pages, frames, bytes, slices, or other suitable groups. In various embodiments, a memory partition 122 may include any of the volatile or non-volatile memories listed above or other suitable memory. In a particular embodiment, each memory partition 122 comprises one or more 3D crosspoint memory arrays. 3D crosspoint arrays are described in more detail in connection with the following figures.

In various embodiments, storage device 106 may comprise a solid state drive; a memory card; a Universal Serial Bus (USB) drive; a Non-Volatile Dual In-line Memory Module (NVDIMM); storage integrated within a device such as a smartphone, camera, or media player; or other suitable mass storage device.

In a particular embodiment, one or more memory chips 116 are embodied in a semiconductor package. In various embodiments, a semiconductor package may comprise a casing comprising one or more semiconductor chips (also referred to as dies). A package may also comprise contact pins or leads used to connect to external circuits. In various embodiments, a memory chip may include one or more memory partitions 122.

Accordingly, in some embodiments, storage device 106 may comprise a package that includes a plurality of chips that each include one or more memory partitions 122. However, a storage device 106 may include any suitable arrangement of one or more memory partitions and associated logic in any suitable physical arrangement. For example, memory partitions 122 may be embodied in one or more different physical mediums, such as a circuit board, semiconductor package, semiconductor chip, disk drive, other medium, or any combination thereof.

Storage device 106 may include any suitable interface to communicate with CPU memory controller 112 or I/O controller 110 using any suitable communication protocol such as a DDR-based protocol, PCI, PCIe, CXL, USB, SAS, SATA, FC, System Management Bus (SMBus), or other suitable protocol. A storage device 106 may also include a communication interface to communicate with CPU memory controller 112 or I/O controller 110 in accordance with any suitable logical device interface specification such as NVMe, AHCI, or other suitable specification. In particular embodiments, storage device 106 may comprise multiple communication interfaces that each communicate using a separate protocol with CPU memory controller 112 and/or I/O controller 110.

Storage device controller 118 may include logic to receive requests from CPU 102 (e.g., via CPU memory controller 112 or I/O controller 110), cause the requests to be carried out with respect to the memory chips 116, and provide data associated with the requests to CPU 102 (e.g., via CPU memory controller 112 or I/O controller 110). Controller 118 may also be operable to detect and/or correct errors encountered during memory operations via an error correction code (ECC engine). In an embodiment, controller 118 also tracks, e.g., via a wear leveling engine, the number of times particular cells (or logical groupings of cells) have been written to in order to perform wear leveling, detect when cells are nearing an estimated number of times they may be reliably written to, and/or adjust read operations based on the number of times cells have been written to. In performing wear leveling, the storage device controller 118 may evenly spread out write operations among the cells of memory chips 116 in an attempt to equalize the number of operations (e.g., write operations) performed by each cell. In various embodiments, controller 118 may also monitor various characteristics of the storage device 106 such as the temperature or voltage and report associated statistics to the CPU 102. Storage device controller 118 can be implemented on the same circuit board or device as the memory chips 116 or on a different circuit board or device. For example, in some environments, storage device controller 118 may be a centralized storage controller that manages memory operations for multiple different storage devices 106 of computer system 100.

In various embodiments, the storage device 106 also includes program control logic 124 which is operable to control the programming sequence performed when data is written to or read from a memory chip 116. In various embodiments, program control logic 124 may provide the various voltages (or information indicating which voltages should be provided) that are applied to memory cells during the programming and/or reading of data (or perform other operations associated with read or program operations), perform error correction, and perform other suitable functions.

In various embodiments, the program control logic 124 may be integrated on the same chip as the storage device controller 118 or on a different chip. In the depicted embodiment, the program control logic 124 is shown as part of the storage device controller 118, although in various embodiments, all or a portion of the program control logic 124 may be separate from the storage device controller 118 and communicably coupled to the storage device controller 118. For example, all or a portion of the program control logic 124 described herein may be located on a memory chip 116. In various embodiments, reference herein to a “controller” may refer to any suitable control logic, such as storage device controller 118, chip controller 126, or a partition controller. In some embodiments, reference to a controller may contemplate logic distributed on multiple components, such as logic of a storage device controller 118, chip controller 126, and/or a partition controller.

In various embodiments, storage device controller 118 may receive a command from a host device (e.g., CPU 102), determine a target memory chip for the command, and communicate the command to a chip controller 126 of the target memory chip. In some embodiments, the storage device controller 118 may modify the command before sending the command to the chip controller 126.

In various embodiments, the storage device controller 118 may send commands to memory chips 116 to perform host-initiated read operations as well as device-initiated read operations. A host-initiated read operation may be performed in response to reception of a read command from a host coupled to the storage device 106, such as CPU 102. A device-initiated read operation may be a read operation that is performed in response to a device-initiated read command generated by the storage device 106 independent of receiving a read command from the host. In various embodiments, the storage device controller 118 may be the component that generates device-initiated read commands. The storage device 106 may initiate a device-initiated read command for any suitable reason. For example, upon power up of a storage device, the storage device 106 may initiate a plurality of read and write-back commands to re-initialize data of the storage device 106 (e.g., to account for any drift that has occurred while the storage device 106 or a portion thereof was powered off or has sat idle for a long period of time).

The chip controller 126 may receive a command from the storage device controller 118 and determine a target memory partition 122 for the command. The chip controller 126 may then send the command to a controller of the determined memory partition 122. In various embodiments, the chip controller 126 may modify the command before sending the command to the controller of the partition 122.

In some embodiments, all or some of the elements of system 100 are resident on (or coupled to) the same circuit board (e.g., a motherboard). In various embodiments, any suitable partitioning between the elements may exist. For example, the elements depicted in CPU 102 may be located on a single die (i.e., on-chip) or package or any of the elements of CPU 102 may be located off-chip or off-package. Similarly, the elements depicted in storage device 106 may be located on a single chip or on multiple chips. In various embodiments, a storage device 106 and a computing host (e.g., CPU 102) may be located on the same circuit board or on the same device and in other embodiments the storage device 106 and the computing host may be located on different circuit boards or devices.

The components of system 100 may be coupled together in any suitable manner. For example, a bus may couple any of the components together. A bus may include any known interconnect, such as a multi-drop bus, a mesh interconnect, a ring interconnect, a point-to-point interconnect, a serial interconnect, a parallel bus, a coherent (e.g. cache coherent) bus, a layered protocol architecture, a differential bus, and a Gunning transceiver logic (GTL) bus. In various embodiments, an integrated I/O subsystem includes point-to-point multiplexing logic between various components of system 100, such as cores 114, one or more CPU memory controllers 112, I/O controller 110, integrated I/O devices, direct memory access (DMA) logic (not shown), etc. In various embodiments, components of computer system 100 may be coupled together through one or more networks comprising any number of intervening network nodes, such as routers, switches, or other computing devices. For example, a computing host (e.g., CPU 102) and the storage device 106 may be communicably coupled through a network.

Although not depicted, system 100 may use a battery and/or power supply outlet connector and associated system to receive power, a display to output data provided by CPU 102, or a network interface allowing the CPU 102 to communicate over a network. In various embodiments, the battery, power supply outlet connector, display, and/or network interface may be communicatively coupled to CPU 102. Other sources of power can be used such as renewable energy (e.g., solar power or motion based power).

Storage device SRAM 130 and chip SRAM 128 each are adapted to execute internal firmware or software of the storage device 106 and memory chip 116 respectively. For example, the logic to be implemented by program control logic 124, upon the issuance of a command, for example from the host or CPU 102 to execute the logic, may be moved from a memory storing the logic to SRAM 130 (such as a NVM—not shown) such that the logic may be executed by the storage device controller 118 which will have access to the logic instructions by way of the associated SRAM 128. Similarly, the logic to be implemented by the chip controller 126, upon the issuance of a command, for example from the host or CPU 102 to execute the logic, may be moved from a memory storage the logic to the associated SRAM 128 (such as a NVM—not shown) such that the logic may be executed by the associated chip controller 126 which will have access to the logic instructions by way of the associated SRAM 128.

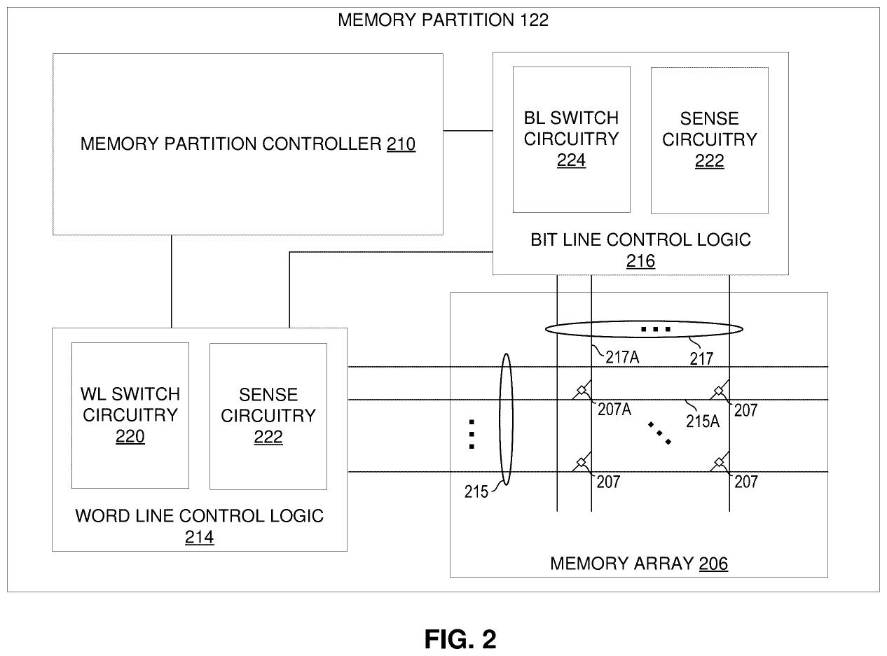

FIG. 2 illustrates a detailed exemplary view of the memory partition 122 of FIG. 1 in accordance with certain embodiments. In one embodiment, a memory partition 122 may include 3D crosspoint memory which may include phase change memory or other suitable memory types. In a particular embodiment, phase change memory may utilize a chalcogenide material for memory elements. A memory element is a unit of a memory cell that actually stores the information. In operation, phase change memory may store information on the memory element by changing the phase of the memory element between amorphous and crystalline phases. The material of a memory element (e.g., the chalcogenide material) may exhibit either a crystalline or an amorphous phase, exhibiting a low or high conductivity. Generally, the amorphous phase has a low conductivity (high impedance) and is associated with a reset state (logic zero) and the crystalline phase has a high conductivity (low impedance) and is associated with a set state (logic one). The memory element may be included in a memory cell 207 (e.g., a phase change memory cell) that also includes a selector, i.e., a selector device coupled to the memory element. The selector devices are configured to facilitate combining a plurality of memory elements into an array.

In some embodiments, a 3D crosspoint memory array 206 may comprise a transistor-less (i.e., at least with respect to the data storage elements of the memory) stackable crosspoint architecture in which memory cells 207 sit at the intersection of row address lines and column address lines arranged in a grid. The row address lines 215 and column address lines 217, called word lines (WLs) and bit lines (BLs), respectively, cross in the formation of the grid and each memory cell 207 is coupled between a WL and a BL where the WL and BL cross (i.e., crosspoint). At the point of a crossing, the WL and BL may be located at different vertical planes such that the WL crosses over the BL but does not physically touch the BL. As described above, the architecture may be stackable, such that a word line may cross over a bit line located beneath the word line and another bit line for another memory cell located above the word line. It should be noted that row and column are terms of convenience used to provide a qualitative description of the arrangement of WLs and BLs in crosspoint memory. In various embodiments, the cells of the 3D crosspoint memory array may be individually addressable. In some embodiments, bit storage may be based on a change in bulk resistance of a 3D crosspoint memory cell. In various embodiments, 3D crosspoint memory may include any of the characteristics of 3D XPoint memory manufactured by INTEL CORPORATION and/or MICRON TECHNOLOGY, INC.

During a programming operation (i.e., a write operation), the phase of the memory element may be changed by the application of a first bias voltage to the WL and a second bias voltage to the BL resulting in a differential bias voltage across the memory cell that may cause a current to flow in the memory element. The differential bias voltage may be maintained across the memory cell for a time period sufficient to cause the memory element to transition the memory element from the amorphous state to the crystalline state or from the crystalline state to the amorphous state (e.g., via the application of heat produced by an electric current). Snap back is a property of the composite memory element that results in an abrupt change in conductivity and an associated abrupt change in the voltage across the memory element. For example, a “snapback” may be used to refer to an instance where the transition from subthreshold to the threshold or above threshold region of a cell may involve an event where the voltage sustained by the target cell for a given current through the cell is suddenly reduced.

In a read operation, a target memory cell is selected via the application of a first bias voltage to the WL and a second bias voltage to the BL that cross at the target memory cell for a time interval. A resulting differential bias voltage (a demarcation read voltage (VDM)) across the memory element is configured to be greater than a maximum set voltage and less than a minimum reset voltage for the memory element.

In response to application of the VDM, the target memory element may or may not snap back, depending on whether the memory element is in the crystalline state (set) or the amorphous state (reset). Sense circuitry, coupled to the memory element, is configured to detect the presence or absence of snap back in a sensing time interval. The presence of snap back may then be interpreted as a logic one and the absence of snap back as a logic zero.

The differential bias at which a memory cell transitions from being sensed as a logic one (e.g., due to the memory cell snapping back) to being sensed as a logic zero (e.g., due to the memory cell not snapping back), may be termed a threshold voltage (sometimes referred to as a snap back voltage). Thus, when the VDM is higher than the threshold voltage of the memory cell, the memory cell may be sensed as storing a logic one and when the VDM is lower than the threshold voltage of the memory cell, the memory cell may be sensed as storing a logic zero.

For a write operation or a read operation, one memory cell 207A out of many cells, such as thousands of cells, may be selected as the target cell for the read or write operation, the cell being at the cross section of a BL 217A and a WL 215A. All cells coupled to BL 217A, and all cells coupled to WL 215A other than cell 207A may still see approximately ½ of VDM, with only cell 207A seeing the full VDM.

In the embodiment of FIG. 2, a memory partition 122 includes memory partition controller 210 (or memory controller 210), word line control logic 214, bit line control logic 216, and memory array 206. A host device (e.g., CPU 102) may provide read and/or write commands including memory address(es) and/or associated data to memory partition 122 (e.g., via storage device controller 118 and chip controller 126) and may receive read data from memory partition 122 (e.g., via the chip controller 126 and storage device controller 118). Similarly, storage device controller 118 may provide host-initiated read and write commands or device-initiated read and write commands including memory addresses to memory partition 122 (e.g., via chip controller 126). Memory partition controller 210 (in conjunction with word line control logic 214 and bit line control logic 216) is configured to perform memory access operations, e.g., reading one or more target memory cells and/or writing to one or more target memory cells. Although not depicted, memory partition controller 210 may include an interface to couple the same to the word line control logic (or control circuitry) 214 and bit line control logic (or control circuitry 216).

Memory array 206 corresponds to at least a portion of a 3D crosspoint memory (e.g., that may include phase change memory cells or other suitable memory cells) and includes a plurality of word lines 215, a plurality of bit lines 217 and a plurality of memory cells, e.g., memory cells 207. Each memory cell is coupled between a word line (“WL”) and a bit line (“BL”) at a crosspoint of the WL and the BL. Each memory cell includes a memory element configured to store information and may include a memory cell selector device (i.e., selector) coupled to the memory element. Selector devices may include ovonic threshold switches, such as those including glassy films (e.g. Ge-Sb-Se-N(GSSN) glassy thin films/chalcogenide glass thin films), diodes, bipolar junction transistors, field-effect transistors, etc. Memory array 206 may be configured to store binary data and may be written to (i.e., programmed) or read from.

Memory partition controller 210 may manage communications with chip controller 126 and/or storage device controller 118. In a particular embodiment, memory partition controller 210 may analyze one or more signals received from another controller to determine whether a command sent via a bus is to be consumed by the memory partition 122. For example, controller 210 may analyze an address of the command and/or a value on an enable signal line to determine whether the command applies to the memory partition 122. Controller 210 may be configured to identify one or more target WLs and/or BLs associated with a received memory address (this memory address may be a separate address from the memory partition address that identifies the memory partition 122, although in some embodiments a portion of an address field of a command may identify the memory partition while another portion of the address field may identify one or more WLs and/or BLs). Memory partition controller 210 may be configured to manage operations of WL control logic 214 and BL control logic 216 based, at least in part, on WL and/or BL identifiers included in a received command.

WL control logic 214 includes WL switch circuitry 220 and sense circuitry 222. WL control logic 214 is configured to receive target WL address(es) from memory partition controller 210 and to select one or more WLs for reading and/or writing operations. For example, WL control logic 214 may be configured to select a target WL by coupling a WL select bias voltage to the target WL. WL control logic 214 may be configured to deselect a WL by decoupling the target WL from the WL select bias voltage and/or by coupling a WL deselect bias voltage to the WL. WL control logic 214 may be coupled to a plurality of WLs 215 included in memory array 206. Each WL may be coupled to a number of memory cells corresponding to a number of BLs 217. WL switch circuitry 220 may include a plurality of switches, each switch configured to couple (or decouple) a respective WL, e.g., WL 215A, to WL select bias voltage to select the respective WL 215A. For example, switch circuitry 220 may include a plurality of transistors.

BL control logic 216 includes BL switch circuitry 224. In some embodiments, BL control logic 216 may also include sense circuitry, e.g., sense circuitry 222. BL control logic 216 is configured to select one or more BLs for reading and/or writing operations. BL control logic 216 may be configured to select a target BL by coupling a BL select bias voltage to the target BL. BL control logic 216 may be configured to deselect a BL by decoupling the target BL from the BL select bias voltage and/or by coupling a BL deselect bias voltage to the BL. BL switch circuitry 224 is similar to WL switch circuitry 220 except BL switch circuitry 224 is configured to couple the BL select bias voltage to a target BL.

Sense circuitry 222 is configured to detect the state of one or more sensed memory cells 207 (e.g., via the presence or absence of a snap back event during a sense interval), e.g., during a read operation. Sense circuitry 222 is configured to provide a logic level output related to the result of the read operation to, e.g., memory partition controller 210. For example, a logic level corresponding to a logic one may be output if the applied VDM is higher than the memory cell's threshold voltage or a logic zero if the applied VDM is lower than the memory cell's threshold voltage. In a particular embodiment, a logic one may be output if a snap back is detected and a logic zero may be output if a snap back is not detected.

As an example, in response to a signal from memory partition controller 210, WL control logic 214 and BL control logic 216 may be configured to select one or more target memory cells, e.g., memory cell 207A, for a read operation by coupling WL 215A to WL select bias voltage and BL 217A to BL select bias voltage. One or both of sense circuitries 222 may then be configured to monitor WL 215A and/or BL 217A for a sensing interval in order to determine the state of the memory cell 207A (e.g., to determine whether or not a snap back event occurs). For example, if a sense circuitry 222 detects a snap back event, then memory cell 207A may be in the set state, but if a sense circuitry 222 does not detect a snap back event in the sensing interval, then memory cell 207A may be in the reset state.

Thus, WL control logic 214 and/or BL control logic 216 may be configured to select a target memory cell for a read operation, initiate the read operation, sense the selected memory cell (e.g., for a snap back event) in a sensing interval, and provide the result of the sensing to, e.g., memory partition controller 210.

In a particular embodiment, the sense circuitry 222 may include a word line (WL) load connected to a WL electrode or gate, and a bit line (BL) load connected to a bit line electrode or gate. When a particular WL and BL are selected in the array, a difference between WL load or WL voltage and the BL voltage correspond to a read VDM. VDM may induce a current in the memory cell 207A, I_{cell}. A comparator such as a sense amplifier may compare I_{cell} with a reference current in order to read a logic state one or logic state zero depending on whether the memory cell is a set cell or a reset cell. The reference current may thus be selected such that the current of the target memory cell is lower than the reference current before snapback of the target memory cell and higher than the reference current after snapback of the target memory cell. In this manner, an output of the sense amplifier/comparator may be indicative of a state of the target memory cell. A latch may be coupled to the output of the comparator to store the output of the read operation. In some embodiments, leakage components of the current can be mitigated by respectively selecting a bias for all other unselected wordlines and bitlines that reduces or minimizes leakage. Capacitive components of the current can be mitigated by allowing sufficient time for the capacitive components to dissipate.

For each matrix of arrays, there may be a sense amplifier provided. Each partition 122 may have 128 such matrices, hence 128 sense amplifiers. Each partition may be read from one read operation.

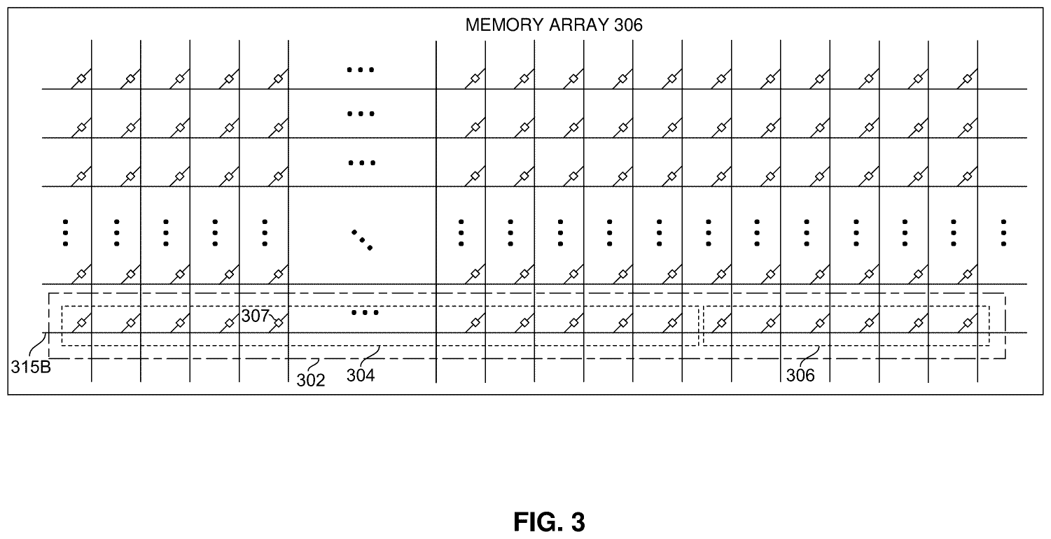

FIG. 3 illustrates a detailed exemplary view of the memory array 206 of FIG. 2 in accordance with certain embodiments. In various embodiments, a plurality of memory cells 207 of memory array 206 may be divided into a logical group such as a slice 302 (and the memory array 206 may include a plurality of slices). In the embodiment depicted, slice 302 includes a plurality of memory cells 207 coupled to the same WL 215A, though a slice 302 may comprise any suitable arrangement of memory cells.

In a particular embodiment, a slice may include a payload portion 304 and a metadata portion 306. The memory cells of the payload portion 304 may store data written to the storage device 106 by a host (e.g., CPU 102/104). For example, the host may send a write command specifying payload data to be written to the storage device 106 at a particular logical address. The payload of the write command may be stored in a payload portion 304 of one or more slices 302 (in various embodiments, the payload portion 304 may be large enough to hold payload data from multiple write commands from the host). In various embodiments, the size of the payload portion of a slice may have any suitable size, such as 1 kibibyte (KiB), 2 KiB, 4 KiB, 8 KiB, or other suitable size.

The memory cells of the metadata portion 306 of a slice 302 may store metadata associated with the payload data stored in the payload portion 304 of the slice 302 or the slice itself. The metadata portion 306 may store any suitable metadata associated with the payload data or slice. For example, the metadata portion 306 may store parity bits and/or cyclic redundancy check (CRC) bits used during error detection and error correction, e.g., by the storage device controller 118. In alternative embodiments, error detection and/or correction may be performed at any suitable level on the storage device 106, such as by the chip controllers 126 or partition controllers 210.

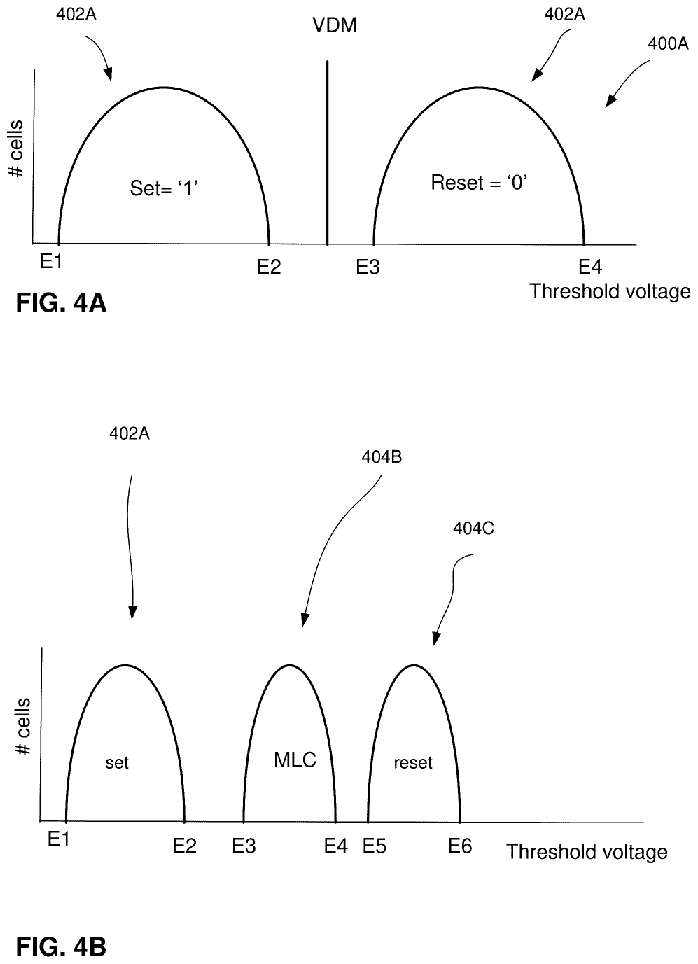

FIG. 4A illustrates a plot or graph 400A depicting memory cell threshold voltage statistical distributions 402A for set cells (storing a bit 1), and 404A for reset cells (storing a bit 0) (these are meant to represent bell curves for example), and a read voltage “VDM” for a single level cell (SLC).

In FIG. 4A, the horizontal axis depicts threshold voltages of memory cells of a single level cell array, and the vertical axis depicts bit counts (i.e., number of memory cells). Thus, each point of a distribution 402A/404A represents several cells having a particular threshold voltage. The graph 400A assumes that half of the bits of the array is in a set state (i.e., has a threshold voltage lower than the corresponding VDM) and half of the bits is in a reset state (i.e., has a threshold voltage higher than the corresponding VDM). Distributions 402A and 404A represents a baseline distribution that may correspond to a threshold voltage distribution at a particular point in time.

In a read operation, a target memory cell, such as cell 207A, is selected via the application of a first bias voltage to the WL 215A and a second bias voltage to the BL 217A that cross at the target memory cell for a time interval. A resulting differential bias voltage (a demarcation read voltage (VDM)) across the memory element is configured to be greater than a maximum set voltage E2 and less than a minimum reset voltage E3 for the memory element.

In response to application of the VDM, the target cell may or may not snap back, depending on whether the target cell is in the crystalline state (set) or the amorphous state (reset), as suggested in FIG. 4A. If the target cell is in a set state, application of the VDM would cause the set cell to snap back, in which case the target cell would be read as a logic one, and if the target cell is in a reset state, application of the VDM, ideally, would not cause the reset cell to snap back, in which case the target cell would be read as a logic zero. Sense circuitry, coupled to the memory cell, is configured to detect the presence or absence of snap back in a sensing time interval. The presence of snap back may then be interpreted as a logic one and the absence of snap back as a logic zero as noted above.

The differential bias at which a memory cell transitions from being sensed as a logic one (e.g., due to the memory cell snapping back) to being sensed as a logic zero (e.g., due to the memory cell not snapping back), may be termed a threshold voltage (sometimes referred to as a snap back voltage). Thus, when the VDM is higher than the threshold voltage of the memory cell as shown in FIG. 4A, the memory cell may be sensed as storing a logic one and when the VDM is lower than the threshold voltage of the memory cell, the memory cell may be sensed as storing a logic zero.

In some embodiments, an applied bias such as the VDM of a read pulse may be high enough to only turn on 3D crosspoint cells in the crystalline state, which may have a lower threshold voltage than 3D crosspoint cells in the amorphous state. In some embodiments, the VDM may be supplied through negative and/or positive regulated nodes. For example, the BL electrode of the 3D crosspoint cell may be a positive regulated node and the WL electrode coupled to the cell may supply the bias for VDM and be a negative regulated node.

FIG. 4A is a graph depicting memory cell threshold voltage distributions and demarcation voltages in accordance with certain embodiments for a single level cell (SLC) memory including selector devices in individual memory cells thereof. In FIG. 4A, a VDM applied between E2 and E3 would provide the necessary voltage to read a logic 1 or logic 0 depending on whether the target cell is a set cell or a reset cell.

FIG. 4B is a graph depicting memory cell threshold voltage distributions and demarcation voltages in accordance with certain embodiments for a multi-level cell (MLC) memory including selector devices in individual memory cells thereof. By way of example, FIG. 4B shows a graph similar to FIG. 4A but for a three level MLC memory, including distributions 402B for cells with a first state (set state), 404B for cells with a second state (MLC state), and 406B for cells with a third state (reset state).

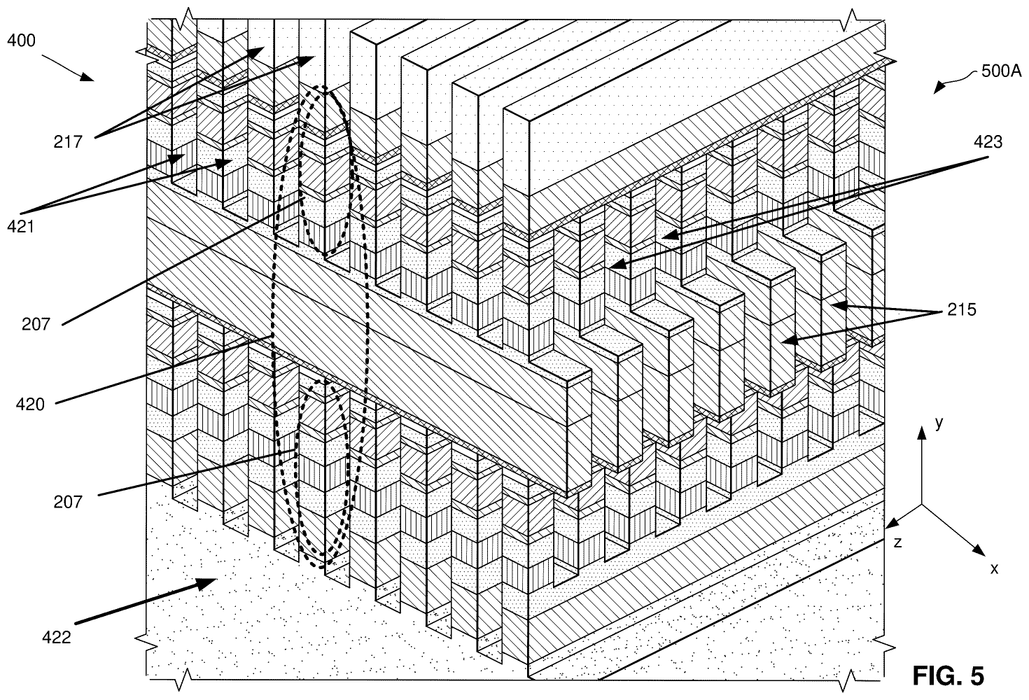

In the following FIGS. 5, 6A, 6B, 7A and 7B, like components will be referred to with like and/or the same reference numerals. Therefore, detailed description of such components may not be repeated from figure to figure.

FIG. 5 is a schematic perspective three-dimensional view of a semiconductor structure for a 3D memory architecture according to some embodiments. In particular, FIG. 5 is a perspective diagram of an example of a portion of stack 500 of a 3D crosspoint memory device including memory arrays such as those of FIGS. 2 and 3. The specific layers are merely examples and will not be described in detail here. Stack 500 is built on substrate structure 522, such as silicon or another semiconductor. Stack 500 includes multiple pillars 520 as memory cell stacks of memory cells 207. In the diagram of stack 500, it will be observed that the WLs and BLs are orthogonal to each other, and traverse or cross each other in a cross-hatch pattern. A crosspoint memory structure includes at least one memory cell in a stack between layers of BL and WL. As illustrated, wordlines (WL) 215 are in between layers of elements, and bitlines (BL) 217 are located at the top of the circuit. Such a configuration is only an example, and the BL and WL structure can be swapped. Thus, in one representation of stack 500, the WLs can be the metal structures labeled as 217, and the BLs can be the metal structures labeled as 215. More generically, WLs and BLs can be referred to as “address lines”, referring to signal lines used to address memory cells. Different architectures can use different numbers of stacks of devices, and different configuration of WLs and BLs. It will be understood that the spaces/trenches 521 running in one direction, and spaces/trenches 523 running in a direction perpendicular to trenches 521, the trenches 521 and 523 being defined between pillars 520, are to be typically filled with an insulator. In one example, in stack 500 the BL and WL are made of tungsten metal.

At least some of WLs 215 may correspond to WLs 215 of FIG. 2. At least some of the BLs 217 may correspond to BLs 217 of FIG. 2. Substrate structure 522, such as a silicon substrate, may include control circuitry therein (not shown), such as control circuitry including transistors, row decoders, page buffers, etc. Memory cells 207 may correspond to memory cells 207 of FIG. 2, and may each include a selector device, and/or a memory element and a selector device. The control circuitry of substrate structure 522 may include, for example, a memory partition controller such as memory partition controller 210, BL control logic such as BL control logic 216, and WL control logic such as WL control logic 214 of FIG. 2. Each row of WLs 215 extending in the y direction, the corresponding cells as coupled to corresponding BLs, would define a memory array, and may correspond to a memory array such as memory array 206 of FIGS. 2 and 3. Some of the WLs and some of the BLs may include dummy WLs or dummy BLs (not shown in FIG. 5), corresponding to the dummy WLs and dummy BLs in the dummy array 206B of FIGS. 2 and 3.

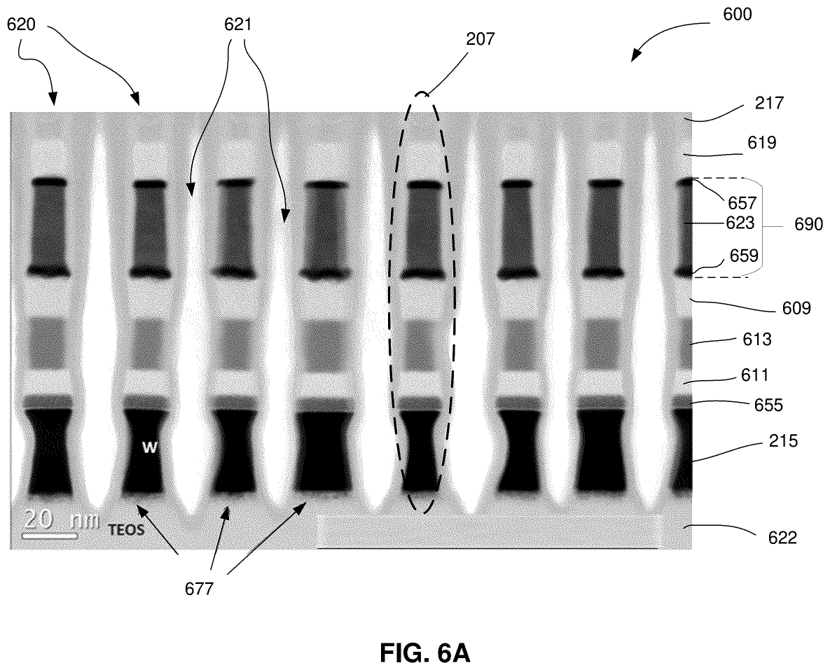

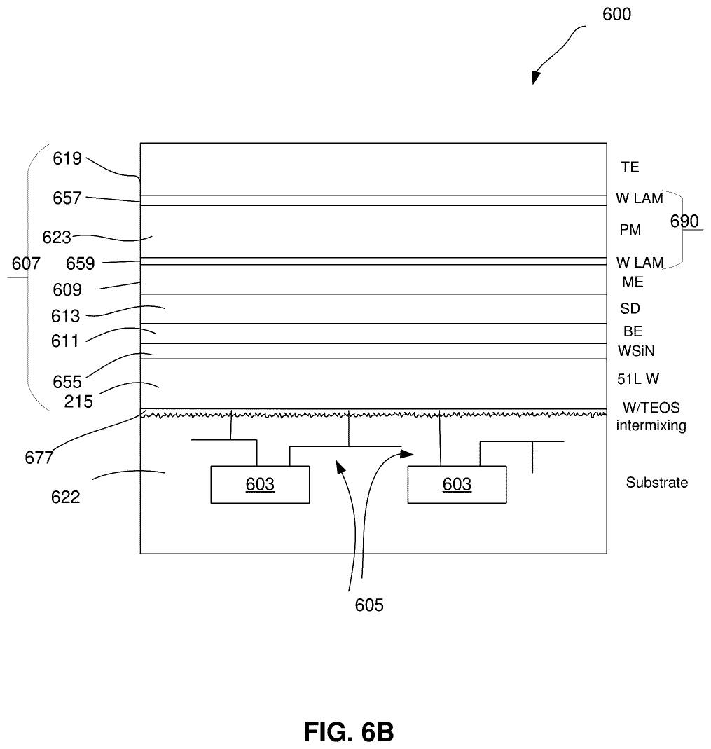

FIG. 6A is a transmission electron microscope (TEM) generated image of a memory architecture 600 comparable to stack, or memory architecture, 600 of FIG. 5.

FIG. 6B is a schematic cross sectional view across a portion 602 of one of the pillars 620 of FIG. 6A.

Referring to FIGS. 6A and 6B together, stack 600 includes memory stack 607 built on substrate structure 622. Substrate structure 622 may include a dielectric material, such as TEOS silicon dioxide by way of example. The underlying substrate structure 622 includes circuitry therein which may include active and/or passive microelectronic devices 603, for example complementary metal oxide semiconductor (CMOS) devices. The circuitry in the substrate structure 622 may also include electrically conductive structures 605 which couple the devices 603 to each other and/or to other devices outside the substrate structure 622, such as to memory cells within memory stack 607 by way of WLs 215. The electrically conductive structure 605 may include interconnects such as traces and vias within the substrate 622, contacts on the substrate surface, such as the top surface of the substrate supporting the memory stack 607.

The memory stack 607 includes multiple pillars 620 as memory cell stacks of memory cells 207 with memory stack 607. WLs 215 and BLs 217 of stack 600 are orthogonal to each other. As illustrated, wordlines (WL) 215 are in between layers of elements, and bitlines (BL) 217 are located at the top of the circuit. Such a configuration is only an example, and the BL and WL structure can be swapped. The trenches 621 are filled with an insulator such as a dielectric material, for example an oxide. In one example, in stack 600 the BL and WL are made of tungsten (W) metal. Memory cells 207 include a middle electrode 609, a bottom electrode 611, and a selector device 613 including a chalcogenide selector device material. A memory element 690 includes a phase change material (PCM) layer 623 shown as having been provided between middle electrode 609 and a topmost electrode 619. As used herein, a memory element include material layers disposed between two electrodes to form part of all of a memory cell. Memory element 690 is shown as including PCM layer 623, and, at a top surface and at a bottom surface of the PCM layer 623, respective PCM liners 657 and 659, which may include, for example, liners including tungsten. Similarly, a liner 655 is shown on a top surface of WL 215, between the WL 215 and the bottom electrode 611, which liner 655 may include, for example, WSiN.

In the current cell architecture as shown by way of example in FIGS. 6A and 6B, the WL interconnect W material is directly deposited on the TEOS dielectric material of substrate 622 on underlying via interconnect included in substrate 622. W is deposited using physical vapor deposition (PVD). To attain the low resistance WLs 215, the deposition process requires striking the plasma used in the PVD with an alternating current (AC) bias applied to the substrate 622, which helps with W-nucleation and growth along the <110> plane. Higher <110> textures have been observed to advantageously give lower resistivity to W films.

However, disadvantageously, the high strike AC bias and related high-power associated with the same to strike the plasma used in the PVD process for the material of the WL to achieve the texture required for low resistivity causes W to intermix with the material of the substrate, creating a metal-dielectric intermixing region 677, and resulting in a resistive leakage path in the substrate 622 which can eventually degrade cell functionality.

In the TEM image at FIG. 6B, the intermixing region 677 may be clearly seen in the form of shadowy, grainy appearing darker regions just under the WLs 215.

The high strike bias can result in a breakdown of the microstructure of the dielectric material of the underlying substrate, leading to surface roughening of the same during PVD deposition of the W material. As a result, when the W material is being deposited, it may lead to a doping of the dielectric material of the underlying substrate structure with W, resulting in the metal-dielectric intermixing region 677. The intermixing region 677 can and often does lead to leakage of electrical signals between the WLs 215 of adjacent pillars, and possibly between the WLs and the underlying circuitry, including the electrically conductive structures 605 and devices 603 within substrate 622.

According to the state of the art, where the space between cell pillars is, for example, about 19.5 nm, measurable leakage between memory cell pillars (e.g., between adjacent WLs) attributable to the intermixing region can already been observed, which degrades the cell performance. It is anticipated that the leakage will be severe, and cell performance will significantly degrade in future nodes where the space between cells are expected to be reduced to 13.5 nm (30% reduction) for n+1 and 10.5 nm (46% reduction) for n+2 nodes, and beyond.

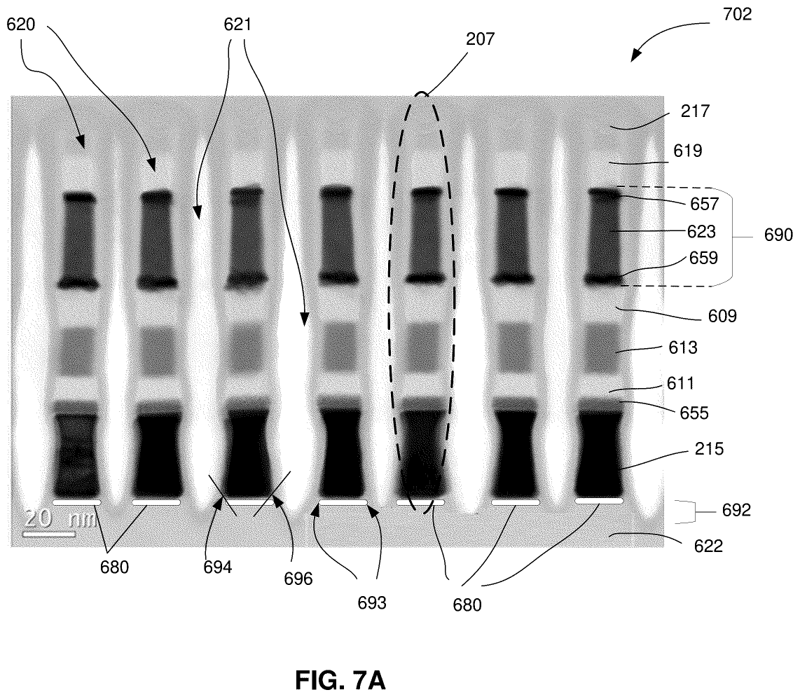

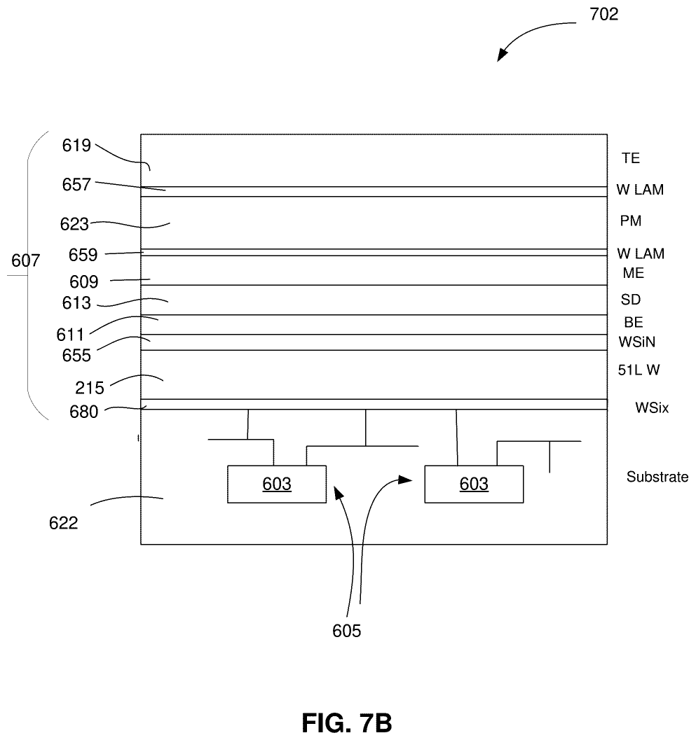

FIG. 7A is a transmission electron microscope (TEM) generated image of a memory architecture 700 comparable to stack, or memory architecture, 600 of FIG. 6, although FIG. 7A includes a layer 680 including a refractory metal between the WL 215 and the underlying substrate 722.

FIG. 7B is a schematic cross sectional view across a portion 702 of one of the pillars 720 of FIG. 7A.

Because of the correlation between FIGS. 7A and 7B on the one hand, and FIGS. 6A and 6B on the other hand, like components are referred to with the same reference numerals. Therefore, detailed description of such components is not repeated in FIGS. 7A and 7B.

In FIGS. 7A and 7B, a barrier layer 680 is provided between WL 215 and the dielectric material of the substrate 622. This barrier layer may include, for example, at least one of: a layer including a refractory metal, or a layer including silicon, carbon and nitrogen. The refractory metal may include, for example, at least one of W or Mo. The refractory metal may include, for example, at least one of W, Mo, Nb, Ta, or Re. The layer including a refractory metal may include, for example, the refractory metal and silicon. For example the layer may include a refractory metal silicide. The refractory metal silicide may include, for example, WSix or MoSix. The layer including a refractory metal may include, for example, a solid solution. The solid solution may include, for example, two or more of W, Mo, Nb, Ta, or Re. The solid solution may include, for example, Cr with one or more of W, Mo, Nb, Ta, or Re. The layer including Si, C and N may include, for example, SiCN. Thus, an electron energy loss spectroscopy (EELS) or Energy-dispersive X-ray spectroscopy (EDS) as applied along a cross section or line LS of the stack 702 may show a concentration of the metal material of the WL 215 decrease at an interface with the barrier layer 680, and concentrations of any of the elements noted above for the barrier layer increase, with substantially no intermixing region that includes a metal of the WL with the dielectric material of the underlying substrate.

The barrier layer may have a thickness of about 15 Angstroms to 25 Angstroms, by way of example.

The barrier layer may be deposited one or more of PVD, CVD, ALD, or electrodeposition. A deposition temperature of the barrier layer may be between 100 about 300 degrees Centigrade.

According to method embodiment, a composition of the barrier layer is based on a predetermined or desired tensile stress to be achieved in the memory stack by virtue of the presence of the barrier layer, or based on a predetermined degree of leakage prevention for leakage as between adjacent WLs of a memory stack.

A material of the barrier layer may be either amorphous or crystalline, and may further include dopants, such as oxygen.

The barrier layer substantially prevents intermixing of the metal of the WL with the dielectric material of the underlying substrate structure.

In general, a barrier layer such as the one described herein prevents the formation of a conduction path between physically separate first and second electrically conductive structures, especially when formation of at least one of the first or second electrically conductive structures involves the application of a high bias to plasma used in a PVD process to deposit the material of the first and second electrically conductive structure on a surface of a dielectric body.

First, as suggested by FIGS. 7A and 7B there is substantially no intermixing region between the W of the WL and the dielectric material of the substrate 622, and this by virtue of the presence of the barrier layer 680. In addition, provision of the barrier layer 680 may, according to an embodiment, lead to a configuration of the WLs that includes, at a bottom region 692 of the WL, in a cross sectional view of a memory pillar in a plane substantially perpendicular to a length direction of the WL, rounded or non-sharp corners 693. The rounded corners, as shown in FIG. 7A, define tangents respectively having a negative slope 694 and a positive slope 696 defined at corners of the bottom region 692. The non-sharp or rounded corners 693 may be created during an etch process of layers corresponding to layers corresponding to the memory element 690 and underlying layers including electrode layers and the select device layer to form the pillars 620 (FIG. 6A). During the etch, which may include the dry etch, an etch rate of the material of the barrier layer may be larger than the etch rate of the metal material of the WL. In that case, the etch may undercut the metal material of the WL by etching the material of the barrier layer faster, and then etch the corners of the WL region to create the rounded corners 693. In such as case, a reentrance region under the WL 215 is formed which corresponds to regions of the rounded corners 693, at the bottom of the memory stack 607. For example, a radius of curvature at the reentrance regions or rounded corners 693 may be less than about 1 nm.

As can be seen in the example of FIGS. 7A and 7B, some embodiments provide a refractory metal silicide (e.g., WSix) or refractory metal solid solution alloy (e. g., W-Cr) layer on top of the dielectric (TEOS, Carbon doped oxide, low-k, or ultra-low-k oxide) and under the WL tungsten which would in turn prevent the intermixing of the word line (WL) tungsten with dielectric substrates. The schematic of Invention structure is shown in FIG. 3 and a TEM x-section in FIG. 4.

Advantageously, providing a barrier layer between the WL and the underlying substrate structure substantially prevents an intermixing of the metal of the WL with the dielectric material of the substrate structure. The above helps to substantially eliminate the resistive leakage path between the cells, and thus, at a given threshold voltage Vt, the set/reset process is improved, and at a given cell current I3 cell leakage is improved.

In addition, memory cell stacks are required to have tensile stress for structural stability during the downstream etch to form the memory stack pillars. Deposition of tungsten on dielectric may produce about a 850 MPa tensile stress. However, addition of a thin film of WSix of between about 15 and about 25 A can significantly improve the tensile stress of the stacks to about 2500 MPa.

An example method embodiment to provide a 3D memory architecture includes providing a substrate structure including circuitry therein; depositing a barrier layer on the substrate structure, depositing, on the barrier layer, a word line (WL) layer, a first electrode layer on the WL layer, a memory element layer on the first electrode layer, and a second electrode layer on the memory element layer, the memory element layer including a phase change material.

After deposition of the second electrode layer, subtractive etching (or “first cut”) may be performed in the z direction (that is, in a direction that creates pillars having heights extending in the y direction and disposed in rows extending in the z direction, as shown in FIG. 5 and FIGS. 7A and 7B), to form memory pillars 620 up to the top electrodes 619. Thereafter, exposed sides of the cell stacks may be sealed, and trenches defined between the pillars filled with a dielectric material, such as one including silicon and oxygen, to define spacers between the pillars. Thereafter, a chemical mechanical polishing (CMP) of a top surface of the pillars may be performed, and then a BL layer deposited thereon. Thereafter, another substrative etching process (or “second cut”) may be performed in the x direction (that is, in a direction that creates pillars having heights extending in the y direction and disposed in rows extending in the x direction, as shown in FIG. 5 and FIGS. 7A and 7B), with this second cut stopping at a top surface of the WL, in this manner forming an array of memory cell pillars as shown in FIG. 5. The seal layer may be selectively removed to expose cell contacts, and spaces between the pillars extending in the y direction may be filled with a dielectric material, such as one including silicon and oxygen. The latter process may be followed by additional CMP and dry etch back to form a 3D memory cell array.

Optionally, the first electrode layer is a bottom electrode layer, and the second electrode layer is a top most electrode layer that is to be coupled to a bit line (BL), and the memory stack includes a select device layer on the first electrode layer, and a third electrode layer on the select device layer, the third electrode layer corresponding to a middle electrode layer. The circuitry in the substrate may correspond to CMOS circuitry including CMOS devices and associated interconnects.

The memory element may include a phase change memory material such as a chalcogen material, and top and bottom contacts (such as contact layers 657 and 659) on a top surface and bottom surface, respectively, of the phase change memory material. A thermal profile layer may be deposited on a top surface of the top electrode, and then a BL layer provided thereon.

The layers in a memory architecture according to some embodiments may be provided using at least one of PVD, chemical vapor deposition (CVD), ALD, electrodeposition, that is, any one or more of the latter.

Although embodiments have been described in the context of both SLC and MLC memories, they may be also applicable also to triple level cell (TLC) memories, quad level cell (QLC) memories, penta level cell (PLC) memories, or any other memories involving a memory cell array with chalcogenide selector devices as part of its memory cells. In a SLC memory, each memory cell has two voltage levels corresponding to two states (0, 1) to represent one bit. In a MLC, TLC and QLC memory, each memory cell stores two or more bits. Each cell in a MLC memory may use four voltage levels corresponding to four states (00, 01, 10, 11) to represent 2 bits of binary data. Each cell in a TLC memory uses eight voltage levels corresponding to eight states (000 to 111) to represent 3 bits of binary data. Each cell in a QLC memory uses sixteen voltage levels corresponding to sixteen states (0000 to 1111) to represent 4 bits of binary data. In one example, each cell's threshold voltage is indicative of the data that is stored in the cell.

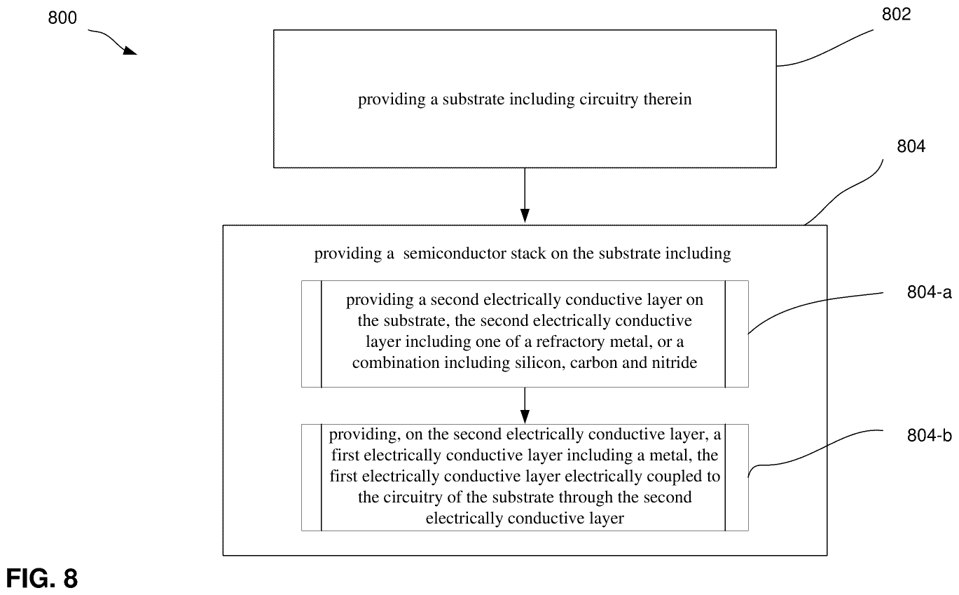

FIG. 8 illustrates an example of a process 800 according to some embodiments. The process includes, at operation 802, providing a substrate including circuitry therein. The process includes, at operation 804, providing a semiconductor stack on the substrate. Operation 804 includes, at sub-operation 804-a, providing a second electrically conductive layer on the substrate, the second electrically conductive layer including one of a refractory metal, or a combination including silicon, carbon and nitride; and at sub-operation 804-b, providing, on the second electrically conductive layer, a first electrically conductive layer including a metal, the first electrically conductive layer electrically coupled to the circuitry of the substrate through the second electrically conductive layer.

The flow described in FIG. 8 is merely representative of operations that may occur in particular embodiments. In other embodiments, additional operations may be performed by the components of system 100. Various embodiments of the present disclosure contemplate any suitable signaling mechanisms for accomplishing the functions described herein. Some of the operations illustrated in FIG. 8 may be repeated, combined, modified, or deleted where appropriate. Additionally, operations may be performed in any suitable order without departing from the scope of particular embodiments.

A design may go through various stages, from creation to simulation to fabrication. Data representing a design may represent the design in a number of manners. First, as is useful in simulations, the hardware may be represented using a hardware description language (HDL) or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In some implementations, such data may be stored in a database file format such as Graphic Data System II (GDS II), Open Artwork System Interchange Standard (OASIS), or similar format.

In some implementations, software based hardware models, and HDL and other functional description language objects can include register transfer language (RTL) files, among other examples. Such objects can be machine-parsable such that a design tool can accept the HDL object (or model), parse the HDL object for attributes of the described hardware, and determine a physical circuit and/or on-chip layout from the object. The output of the design tool can be used to manufacture the physical device. For instance, a design tool can determine configurations of various hardware and/or firmware elements from the HDL object, such as bus widths, registers (including sizes and types), memory blocks, physical link paths, fabric topologies, among other attributes that would be implemented in order to realize the system modeled in the HDL object. Design tools can include tools for determining the topology and fabric configurations of system on chip (SoC) and other hardware device. In some instances, the HDL object can be used as the basis for developing models and design files that can be used by manufacturing equipment to manufacture the described hardware. Indeed, an HDL object itself can be provided as an input to manufacturing system software to cause the described hardware.

In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable storage medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Logic may be used to implement any of the functionality of the various components such as CPU 102, external I/O controller 104, processor 108, cores 114A and 114B, I/O controller 110, CPU memory controller 112, storage device 106, system memory device 107, memory chip 116, storage device controller 118, address translation engine 120, memory partition 122, program control logic 124, chip controller 126, memory array 306, memory partition controller 310, word line control logic 314, bit line control logic 316, or other entity or component described herein, or subcomponents of any of these.

“Logic” may refer to hardware, firmware, software and/or combinations of each to perform one or more functions. In various embodiments, logic may include a microprocessor or other processing element operable to execute software instructions, discrete logic such as an application specific integrated circuit (ASIC), a programmed logic device such as a field programmable gate array (FPGA), a storage device containing instructions, combinations of logic devices (e.g., as would be found on a printed circuit board), or other suitable hardware and/or software. Logic may include one or more gates or other circuit components. In some embodiments, logic may also be fully embodied as software. Software may be embodied as a software package, code, instructions, instruction sets and/or data recorded on non-transitory computer readable storage medium. Firmware may be embodied as code, instructions or instruction sets and/or data that are hard-coded (e.g., nonvolatile) in storage devices.

Use of the phrase ‘to’ or ‘configured to,’ in one embodiment, refers to arranging, putting together, manufacturing, offering to sell, importing, and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘capable of/to,’ and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example, the decimal number ten may also be represented as a binary value of 1010 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware, or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash storage devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the disclosure may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage medium used in the transmission of information over the Internet via electrical, optical, acoustical or other forms of propagated signals (e.g., carrier waves, infrared signals, digital signals, etc.). Accordingly, the computer-readable medium includes any type of tangible machine-readable storage medium suitable for storing or transmitting electronic instructions or information in a form readable by a machine (e.g., a computer).

### EXAMPLES

Some examples of embodiments are provided below.

Example 1 includes a semiconductor structure comprising: a substrate including circuitry therein; a semiconductor stack on the substrate, the semiconductor stack including: a first electrically conductive layer including a metal and electrically coupled to the circuitry of the substrate; and a second electrically conductive layer between the substrate and the first electrically conductive layer, the second electrically conductive layer including one of a refractory metal, or a combination including silicon, carbon and nitride.

Example 2 includes the subject matter of Example 1, wherein the semiconductor stack includes: a memory element layer disposed on the first electrically conductive layer, the memory element layer including a phase change material; and a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells.

Example 3 includes the subject matter of Example 2, wherein the plurality of first address lines include W.

Example 4 includes the subject matter of Example 3, wherein the plurality of first address lines include a plurality of word lines (WLs).

Example 5 includes the subject matter of Example 2, wherein, at individual ones of the pillars, a bottom region of a corresponding first address line includes, in a cross-section of said individual ones of the pillars, two rounded corners defining tangents that have, respectively, a negative slope and a positive slope.

Example 6 includes the subject matter of Example 5, wherein a radius of curvature of the rounded corners is less than about 1 nm.

Example 7 includes the subject matter of any one of Examples 1-6, wherein the refractory metal includes at least one of W, Mo, Nb, Ta, or Re.

Example 8 includes the subject matter of Example 7, wherein the second electrically conductive layer includes the refractory metal and silicon.

Example 9 includes the subject matter of Example 7, wherein the second electrically conductive layer includes a solid solution including the refractory metal.

Example 10 includes the subject matter of Example 7, wherein the second electrically conductive layer includes a refractory metal silicide.

Example 11 includes the subject matter of Example 10, wherein the refractory metal silicide includes at least one of WSix or MoSix.

Example 12 includes the subject matter of Example 9, wherein the solid solution further includes Cr.

Example 13 includes the subject matter of any one of Examples 1-12, wherein, along a line from and through the first electrically conductive layer toward the substrate: at an interface region of the first electrically conductive layer and the second electrically conductive layer, a concentration of the metal of the first electrically conductive layer decreases and a concentration of one or more respective elements of the second electrically conductive layer increases; and at a region of the substrate adjacent the second electrically conductive layer, there is substantially no trace of the metal of the first electrically conductive layer.

Example 14 includes the subject matter of any one of Examples 1-13, wherein the second electrically conductive layer has a thickness of about 15 Angstroms to about 25 Angstroms.

Example 15 includes the subject matter of any one of Examples 1-14, wherein the second electrically conductive layer includes oxygen.

Example 16 includes a system comprising: a plurality of memory partitions, individual ones of the memory partitions including: a substrate including control circuitry therein; and a semiconductor stack including: a first electrically conductive layer electrically coupled to the control circuitry of the substrate and including a metal; a second electrically conductive layer between the substrate and the first electrically conductive layer, the second electrically conductive layer including one of a refractory metal, or a combination including silicon, carbon and nitride; a memory element layer disposed on the first electrically conductive layer, the memory element layer including a phase change material; a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells of said individual ones of the memory partitions; and a storage device controller coupled to the memory partitions to receive memory requests from a processor, and to access the memory cells based on the memory requests

Example 17 includes the subject matter of Example 16, wherein the semiconductor stack includes: a memory element layer disposed on the first electrically conductive layer, the memory element layer including a phase change material; and a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells.

Example 18 includes the subject matter of Example 17, wherein the plurality of first address lines include W.

Example 19 includes the subject matter of Example 18, wherein the plurality of first address lines include a plurality of word lines (WLs).

Example 20 includes the subject matter of Example 19, wherein, at individual ones of the pillars, a bottom region of a corresponding first address line includes, in a cross-section of said individual ones of the pillars, two rounded corners defining tangents that have, respectively, a negative slope and a positive slope.

Example 21 includes the subject matter of Example 20, wherein a radius of curvature of the rounded corners is less than about 1 nm.

Example 22 includes the subject matter of any one of Examples 16-21, wherein the refractory metal includes at least one of W, Mo, Nb, Ta, or Re.

Example 23 includes the subject matter of Example 22, wherein the second electrically conductive layer includes the refractory metal and silicon.

Example 24 includes the subject matter of Example 22, wherein the second electrically conductive layer includes a solid solution including the refractory metal.

Example 25 includes the subject matter of Example 22, wherein the second electrically conductive layer includes a refractory metal silicide.

Example 26 includes the subject matter of Example 25, wherein the refractory metal silicide includes at least one of WSix or MoSix.

Example 27 includes the subject matter of Example 24, wherein the solid solution further includes Cr.

Example 28 includes the subject matter of any one of Examples 15-27, wherein, along a line from and through the first electrically conductive layer toward the substrate: at an interface region of the first electrically conductive layer and the second electrically conductive layer, a concentration of the metal of the first electrically conductive layer decreases and a concentration of one or more respective elements of the second electrically conductive layer increases; and at a region of the substrate adjacent the second electrically conductive layer, there is substantially no trace of the metal of the first electrically conductive layer.

Example 29 includes the subject matter of any one of Examples 1-28, wherein the second electrically conductive layer has a thickness of about 15 Angstroms to about 25 Angstroms.

Example 30 includes the subject matter of any one of Examples 16-29, wherein the second electrically conductive layer includes oxygen.

Example 31 includes a method to make a semiconductor structure, the method including: providing a substrate including circuitry therein; and providing a semiconductor stack on the substrate including: providing a second electrically conductive layer on the substrate, the second electrically conductive layer including one of a refractory metal, or a combination including silicon, carbon and nitride; and providing, on the second electrically conductive layer, a first electrically conductive layer including a metal, the first electrically conductive layer electrically coupled to the circuitry of the substrate through the second electrically conductive layer.

Example 32 includes the subject matter of Example 31, wherein providing the second electrically conductive layer includes using at least one of physical vapor deposition (PVD), chemical vapor deposition (CVD), atomic layer deposition (ALD) or electrodeposition.

Example 33 includes the subject matter of Example 31, wherein providing the second electrically conductive layer takes place at a temperature between about 100 degrees Centigrade and about 300 degrees Centigrade.

Example 34 includes the subject matter of Example 31, wherein providing the first electrically conductive layer includes using physical vapor deposition (PVD) and subjecting a plasma of the PVD to a strike bias using an alternating current.

Example 35 includes the subject matter of Example 31, wherein the semiconductor stack includes: a memory element layer disposed on the first electrically conductive layer, the memory element layer including a phase change material; and a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells.

Example 36 includes the subject matter of Example 35, wherein the plurality of first address lines include W.

Example 37 includes the subject matter of Example 36, wherein the plurality of first address lines include a plurality of word lines (WLs).

Example 38 includes the subject matter of Example 35, wherein, at individual ones of the pillars, a bottom region of a corresponding first address line includes, in a cross-section of said individual ones of the pillars, two rounded corners defining tangents that have, respectively, a negative slope and a positive slope.

Example 39 includes the subject matter of Example 38, wherein a radius of curvature of the rounded corners is less than about 1 nm.

Example 40 includes the subject matter of any one of Examples 31-39, wherein the refractory metal includes at least one of W, Mo, Nb, Ta, or Re.

Example 41 includes the subject matter of Example 40, wherein the second electrically conductive layer includes the refractory metal and silicon.

Example 42 includes the subject matter of Example 40, wherein the second electrically conductive layer includes a solid solution including the refractory metal.

Example 43 includes the subject matter of Example 40, wherein the second electrically conductive layer includes a refractory metal silicide.

Example 44 includes the subject matter of Example 43, wherein the refractory metal silicide includes at least one of WSix or MoSix.

Example 45 includes the subject matter of Example 42, wherein the solid solution further includes Cr.

Example 46 includes the subject matter of any one of Examples 31-45, wherein, along a line from and through the first electrically conductive layer toward the substrate: at an interface region of the first electrically conductive layer and the second electrically conductive layer, a concentration of the metal of the first electrically conductive layer decreases and a concentration of one or more respective elements of the second electrically conductive layer increases; and at a region of the substrate adjacent the second electrically conductive layer, there is substantially no trace of the metal of the first electrically conductive layer.

Example 47 includes the subject matter of any one of Examples 31-46, wherein the second electrically conductive layer has a thickness of about 15 Angstroms to about 25 Angstroms.

Example 48 includes the subject matter of any one of Examples 31-47, wherein the second electrically conductive layer includes oxygen.

Example 49 includes means for performing the method according to any one of the Examples methods listed above, or to any other processes according to embodiments.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

What is claimed is:

1. A semiconductor structure comprising:
a substrate including circuitry therein; and
a semiconductor stack on the substrate, the semiconductor stack including:
a first electrically conductive layer including a metal and electrically coupled to the circuitry of the substrate; and
a second electrically conductive layer between the substrate and the first electrically conductive layer, the second electrically conductive layer including a refractory metal.

2. The semiconductor structure of claim 1, wherein the semiconductor stack includes:
a memory element layer disposed on the first electrically conductive layer, the memory element layer including a phase change material; and
a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells.

3. The semiconductor structure of claim 2, wherein the plurality of first address lines include W.

4. The semiconductor structure of claim 3, wherein the plurality of first address lines include a plurality of word lines (WLs).

5. The semiconductor structure of claim 2, wherein, at individual ones of the pillars, a bottom region of a corresponding first address line includes, in a cross-section of said individual ones of the pillars, two rounded corners defining tangents that have, respectively, a negative slope and a positive slope.

6. The semiconductor structure of claim 1, wherein the refractory metal includes at least one of W, Mo, Nb, Ta, or Re.

7. The semiconductor structure of claim 6, wherein the second electrically conductive layer includes the refractory metal and silicon.

8. The semiconductor structure of claim 6, wherein the second electrically conductive layer includes a solid solution including the refractory metal.

9. The semiconductor structure of claim 6, wherein the second electrically conductive layer includes at least one of WSix or MoSix.

10. The semiconductor structure of claim 8, wherein the solid solution further includes Cr.

11. The semiconductor structure of claim 1, wherein, along a line from and through the first electrically conductive layer toward the substrate:
at an interface region of the first electrically conductive layer and the second electrically conductive layer, a concentration of the metal of the first electrically conductive layer decreases and a concentration of one or more respective elements of the second electrically conductive layer increases; and
at a region of the substrate adjacent the second electrically conductive layer, there is substantially no trace of the metal of the first electrically conductive layer.

12. A semiconductor structure comprising:
a substrate including circuitry therein; and
a semiconductor stack on the substrate, the semiconductor stack including:
a first electrically conductive layer including a metal and electrically coupled to the circuitry of the substrate; and
a second electrically conductive layer between the substrate and the first electrically conductive layer, the second electrically conductive layer including silicon, carbon and nitride.

13. The semiconductor structure of claim 12, wherein the semiconductor stack includes:
a memory element layer disposed on the first electrically conductive layer, the memory element layer including a phase change material; and
a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells.

14. The semiconductor structure of claim 13, wherein the plurality of first address lines include W.

15. The semiconductor structure of claim 14, wherein the plurality of first address lines include a plurality of word lines (WLs).

16. The semiconductor structure of claim 13, wherein, at individual ones of the pillars, a bottom region of a corresponding first address line includes, in a cross-section of said individual ones of the pillars, two rounded corners defining tangents that have, respectively, a negative slope and a positive slope.

17. The semiconductor structure of claim 16, wherein the solid solution further includes Cr.

18. The semiconductor structure of claim 12, wherein, along a line from and through the first electrically conductive layer toward the substrate:
at an interface region of the first electrically conductive layer and the second electrically conductive layer, a concentration of the metal of the first electrically conductive layer decreases and a concentration of one or more respective elements of the second electrically conductive layer increases; and
at a region of the substrate adjacent the second electrically conductive layer, there is substantially no trace of the metal of the first electrically conductive layer.

19. A system comprising:
a plurality of memory partitions, individual ones of the memory partitions including:
a substrate including control circuitry therein; and
a semiconductor stack including:
a first electrically conductive layer electrically coupled to the control circuitry of the substrate and including a metal;
a second electrically conductive layer between the substrate and the first electrically conductive layer, the second electrically conductive layer including one of a refractory metal, or a combination including silicon, carbon and nitride;
a memory element layer disposed on the first electrically conductive layer, the memory element layer including a phase change material;
a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells of said individual ones of the memory partitions; and
a storage device controller coupled to the memory partitions to receive memory requests from a processor, and to access the memory cells based on the memory requests.

20. The system of claim 19, wherein the semiconductor stack includes:
a memory element layer disposed on the first electrically conductive layer, the memory element layer including a phase change material; and
a third electrically conductive layer disposed on the memory element layer, wherein the first electrically conductive layer defines a plurality of first address lines, the third electrically conductive layer defines a plurality of second address lines, individual ones of the memory element layer between respective pairs of the first address lines and the second address lines, the memory element layer and first and second address lines together defining an array of pillars corresponding to an array of memory cells.
